(19) United States
(12) Patent Application Publication
(10) Pub. No.: US 2014/0145271 A1
(43) Pub. Date: May 29, 2014

(54) STRAIN RELAXATION WITH SELF-ALIGNED NOTCH

(71) Applicant: INTERNATIONAL BUSINESS MACHINES CORPORATION, ARMONK, NY (US)

(72) Inventors: Kangguo Cheng, Schenectady, NY (US); Bruce B. Doris, Brewster, NY (US); Ali Khakifirooz, Mountain View, CA (US); Alexander Reznicek, Troy, NY (US)

(73) Assignee: INTERNATIONAL BUSINESS MACHINES CORPORATION, Armonk, NY (US)

(21) Appl. No.: 13/967,074

(22) Filed: Aug. 14, 2013

Related U.S. Application Data
(63) Continuation of application No. 13/687,515, filed on Nov. 28, 2012.

(51) Int. Cl. H01L 29/78; H01L 27/088

(52) U.S. Cl. CPC H01L 29/78; H01L 27/088
USPC 257/368; 257/288

(57) ABSTRACT

A method for fabricating a semiconductor device includes providing one or more gate structures over a strained semiconductor substrate. One or more spacers are formed on the gate structures. One or more notches are formed in the strained semiconductor substrate. The one or more notches are filled to provide strain relaxation in a channel region of the strained semiconductor substrate.

### RELATED APPLICATION INFORMATION

This application is a Continuation application of copending U.S. patent application Ser. No. 13/687,515 filed on Nov. 28, 2012, incorporated herein by reference in its entirety.

### BACKGROUND

1. Technical Field

The present invention relates to semiconductor fabrication, and more particularly to strain relaxation in a semiconductor device using a self-aligned notch.

2. Description of the Related Art

Significant NFET (N-type field effect transistor) performance enhancement has been demonstrated on ETSOI (extremely thin silicon on insulator) and FinFET (fin field effect transistor) devices fabricated on SSDOI (strained silicon directly on insulator). In particular, when the channel is narrow, the component of the strain in the direction normal to the channel is relaxed and, thus, the initial biaxial tensile strain of the SSDOI layer is transformed into uniaxial tensile strain, which is more beneficial for NFETs. However, tensile strain degrades the performance of PFETs (P-type field effect transistors).

### SUMMARY

A method for fabricating a semiconductor device includes providing one or more gate structures over a strained semiconductor substrate. One or more spacers are formed on the gate structures. One or more notches are formed in the strained semiconductor substrate. The one or more notches are filled to provide strain relaxation in a channel region of the strained semiconductor substrate.

A method for fabricating a semiconductor device includes providing one or more gate structures over a strained semiconductor substrate. One or more spacers are formed on the gate structures. One or more notches are formed in the strained semiconductor substrate, the one or more notches being self-aligned at an edge of the spacers. The one or more notches are filled to provide strain relaxation in a channel region of the strained semiconductor substrate by employing a non-faceted epitaxial growth process.

A semiconductor device includes a strained semiconductor substrate. One or more gate structures are formed over the strained semiconductor substrate. One or more spacers are formed on the one or more gate structures. One or more notches are formed in the strained semiconductor substrate, the one or more notches being filled to provide a transistor device having a relaxed channel region.

These and other features and advantages will become apparent from the following detailed description of illustrative embodiments thereof, which is to be read in connection with the accompanying drawings.

### BRIEF DESCRIPTION OF DRAWINGS

The disclosure will provide details in the following description of preferred embodiments with reference to the following figures wherein:

FIG. 1 is a cross-sectional view of a strained semiconductor substrate including a gate structure and spacers formed thereon, in accordance with one embodiment;

FIG. 2 is a cross-sectional view of the device of FIG. 1 including notches formed self-aligned to the spacers, in accordance with one embodiment;

FIG. 3 is a cross-sectional view of the device of FIG. 2 with raised source/drain regions formed above the strained substrate including the notches by employing a non-faceted epitaxy, in accordance with one embodiment;

FIG. 4 is a cross-sectional view of the device of FIG. 2 with raised source/drain regions formed above the strained substrate including the notches by employing a non-faceted epitaxy followed by a faceted epitaxy, in accordance with one embodiment;

FIG. 5 is a cross-sectional view of the device of FIG. 2 with raised source/drain regions formed above unetched regions of the strained substrate, in accordance with one embodiment;

FIG. 6 is a cross-sectional view of the device of FIG. 5 with a non-faceted epitaxial layer formed above the raised source/drain regions including the notches, in accordance with one embodiment;

FIG. 7 is a side view of a fin field effect transistor device, in accordance with one embodiment; and

FIG. 8 is a block/flow diagram of a method for strain relaxation, in accordance with one embodiment.

### DETAILED DESCRIPTION OF PREFERRED EMBODIMENTS

In accordance with the present principles, a device, layout and fabrication method are provided for strain relaxation. Gate structures are formed above a strained semiconductor substrate, such as, e.g., strained silicon directly on insulator. Notches are formed in the strained substrate to provide strain relaxation in the channel region. Preferably, the notches are self-aligned to an edge of the spacers. The notches may be formed by selectively etching the strained substrate by performing an etch process, such as, e.g., applying etchant gas in an epitaxy chamber, damaging the strained substrate during an etch process used to form the spacer or after spacers are formed, etc.

Raised source/drain regions may be formed, which may include filling the notches with a non-faceted epitaxial layer. In one embodiment, a non-faceted epitaxy is employed to form a non-faceted layer above the strained substrate, including the notches. Non-faceted epitaxial growth is substantially independent of the crystallographic orientation of the semiconductor layer on which the epitaxial layer is grown.

In another embodiment, a two-step epitaxy is performed. First, a non-faceted epitaxy is employed to form a non-faceted layer above the strained substrate, including the notches. A faceted epitaxy is then performed to form a faceted layer above the non-faceted layer. Faceted epitaxial growth is generally dependent on the crystallographic orientation of the semiconductor layer on which the epitaxial layer is grown. Advantageously, the parasitic capacitance between a faceted raised source/drain structure and the gate is smaller than that of a non-faceted raised source/drain structure and the gate.

In another yet embodiment, raised source/drain regions are formed above unetched portions of the strained substrate. Preferably, the raised source/drain regions are formed by employing a faceted epitaxial growth process. A non-faceted epitaxy is employed to form a non-faceted layer above the raised source/drain regions and the notches.

Advantageously, the present principles provide strain relaxation for channel regions of a semiconductor device. Preferably, the present principles are particularly applicable to relieve strain in P-type field effect transistors, however it should be understood that the present principles may also be applicable to N-type field effect transistors as well. If should further be understood that other types of devices are also contemplated, such as, e.g., fin field effect transistors.

It is to be understood that the present invention will be described in terms of a given illustrative architecture having a wafer; however, other architectures, structures, substrate materials and process features and steps may be varied within the scope of the present invention.

It will also be understood that when an element such as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

A design for an integrated circuit chip may be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer may transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The flowchart and block diagrams in the Figures illustrate the architecture, functionality, and operation of possible implementations of systems and methods according to various embodiments of the present invention. It should be noted that, in some alternative implementations, the functions noted in the blocks may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

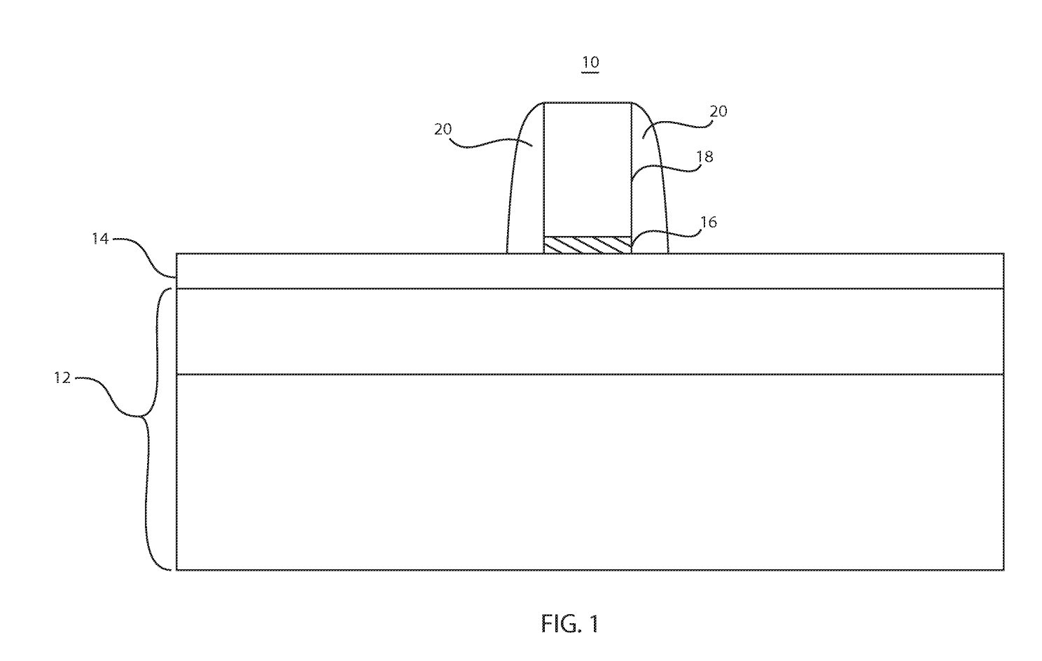

Referring now to the drawings in which like numerals represent the same or similar elements and initially to FIG. 1, a semiconductor device 10 is illustratively shown in accordance with one embodiment. A strained semiconductor layer 14 may be formed in or on a substrate 12 or may be bonded to substrate 12 to form a strained substrate. The strained substrate preferably includes, e.g., a strained semiconductor directly on insulator (SSDOI) substrate. The substrate 12 may include, e.g., a Semiconductor-on-Insulator (SOI) or bulk substrate that may include Gallium, Arsenide, monocrystalline silicon, Germanium, or any other suitable material or suitable combination of materials where the present principles may be applied. The strained semiconductor layer 14 may include, e.g., a variety of strained silicon, silicon germanium, silicon carbon, or a combination thereof

A gate structure includes a gate electrode 18 isolated from the strained substrate by a gate dielectric 16. The gate electrode 18 may include any suitable conductive material, e.g., polycrystalline or amorphous silicon, germanium, silicon germanium, a metal (e.g., tungsten, titanium, tantalum, ruthenium, zirconium, cobalt, copper, aluminum, lead, platinum, tin, silver, gold), a conducting metallic compound material (e.g., tantalum nitride, titanium nitride, tungsten silicide, tungsten nitride, ruthenium oxide, cobalt silicide, nickel silicide), carbon nanotube, conductive carbon, or any suitable combination of these materials. The gate dielectric 16 may include a silicon oxide, silicon nitride, silicon oxynitride, metal oxides, metal oxide-nitride silicates or other suitable materials or combinations of these materials. In some embodiments, the substrate 12 further comprises other features or structures that are formed on or in the semiconductor substrate in previous process steps.

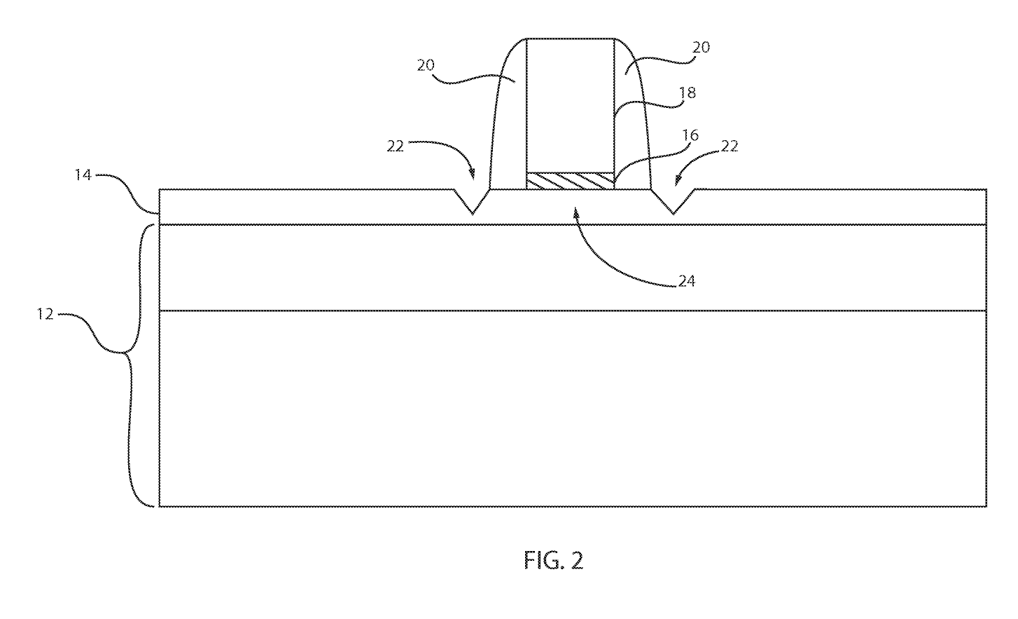

Referring now to FIG. 2, in one embodiment, notches 22 are formed in the strained semiconductor layer 14 to relax the strain in the channel 24. Preferably, the notches 22 are self-aligned to an edge of the spacers 20. The notches 22 are formed by selectively etching the strained semiconductor layer 14. In one embodiment the self-aligned notches are formed by flowing an etchant gas such as, e.g., hydrogen chloride (HCl), or other suitable chlorine containing gases such as SiH₂Cl₂, in an epitaxy chamber. In this case, the self-aligned notch 22 has surfaces defined by (111) facets of the semiconductor channel. In another embodiment, self-aligned notches are formed by damaging the strained semiconductor layer 14 in the vicinity of the spacer during the reactive ion etching (RIE) process used to form the spacer or with a reactive-ion etch process after the spacers are formed. In this embodiment, some of the reacting ions impinging upon the sidewalls of the spacer 20 are bounced back towards the strained layer 14 and form the notches 22 or a damaged portion that can be subsequently removed selectively to the non-damaged portions of the strained layer 14 to form the notches 22. Other embodiments are also contemplated.

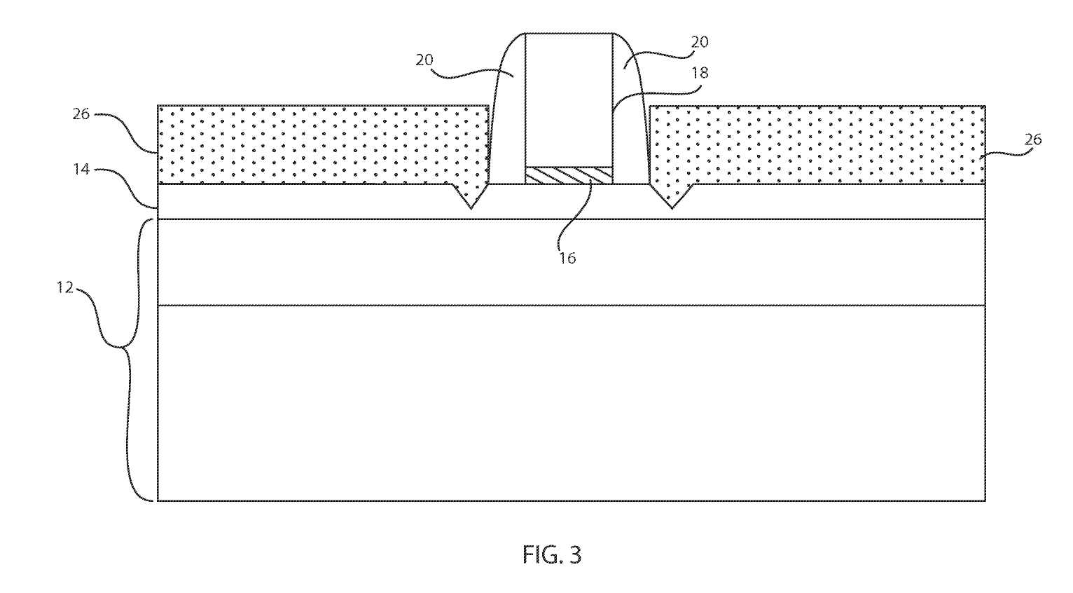

Referring now to FIG. 3, processing of the semiconductor device of FIG. 2 continues to form raised source/drain (S/D) regions 26 over the strained semiconductor layer 14, including the notches 22. A non-faceted epitaxy is preferably employed to form raised S/D regions 26. The non-faceted epitaxy may include epitaxially growing silicon, germanium, silicon germanium, silicon:carbon (Si:C), silicon germanium:carbon (SiGe:C), or other semiconductor materials above the strained semiconductor layer 14. The non-faceted epitaxy growth is a process in which the growth rate is substantially independent of the crystallographic orientation of the semiconductor layer on which the epitaxial layer is grown. In contrast, a faceted epitaxial growth is a process in which the growth rate depends on the crystallographic orientation of the semiconductor layer on which the epitaxial layer is grown. In this case, usually the growth rate in substantially smaller on a (111) orientation than any other crystallographic orientation. As a result, the epitaxy layer is terminated when a (111) surface is formed. Process conditions that allow either non-faceted or faceted growth may be achieved by, e.g., adjusting the growth temperature, pressure, and flow of different gases used in the process.

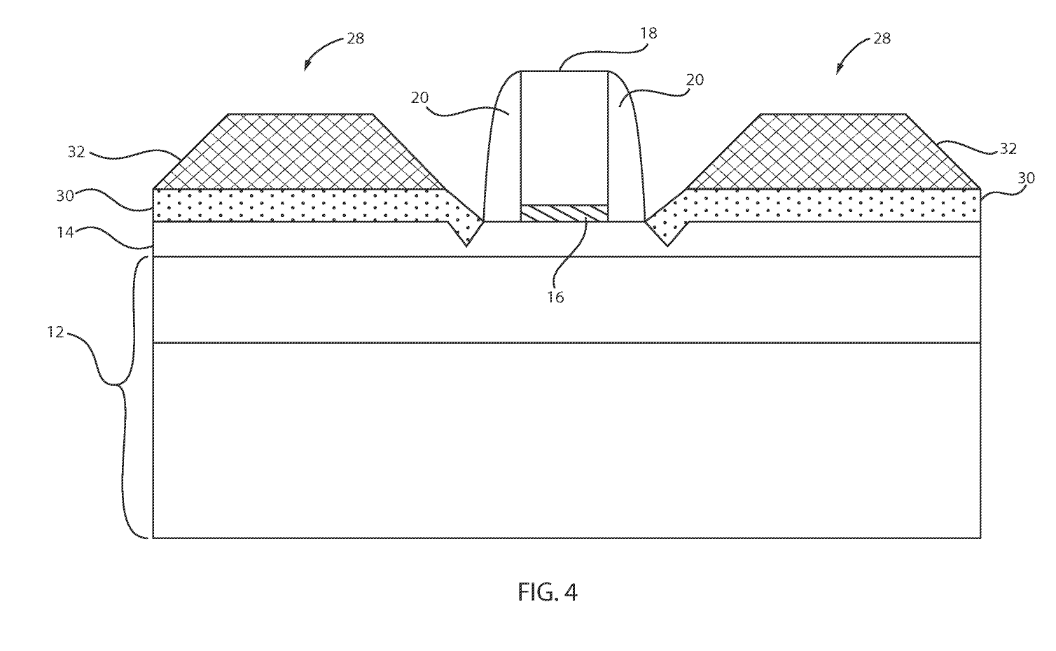

Referring now to FIG. 4, in another embodiment, the semiconductor device of FIG. 2 may be processed to grow S/D regions 28 by employing a two-step epitaxy. A non-faceted epitaxy is first employed to form non-faceted layer 30 above layer 14, including the notches 22. A faceted epitaxy is then employed to form faceted layer 32 over the non-faceted layer 30, at least in part. The parasitic capacitance between a faceted raised S/D structure and the gate is smaller than that of a non-faceted raised S/D and the gate. The epitaxially grown material may include, e.g., silicon germanium, however other semiconductor materials may be employed.

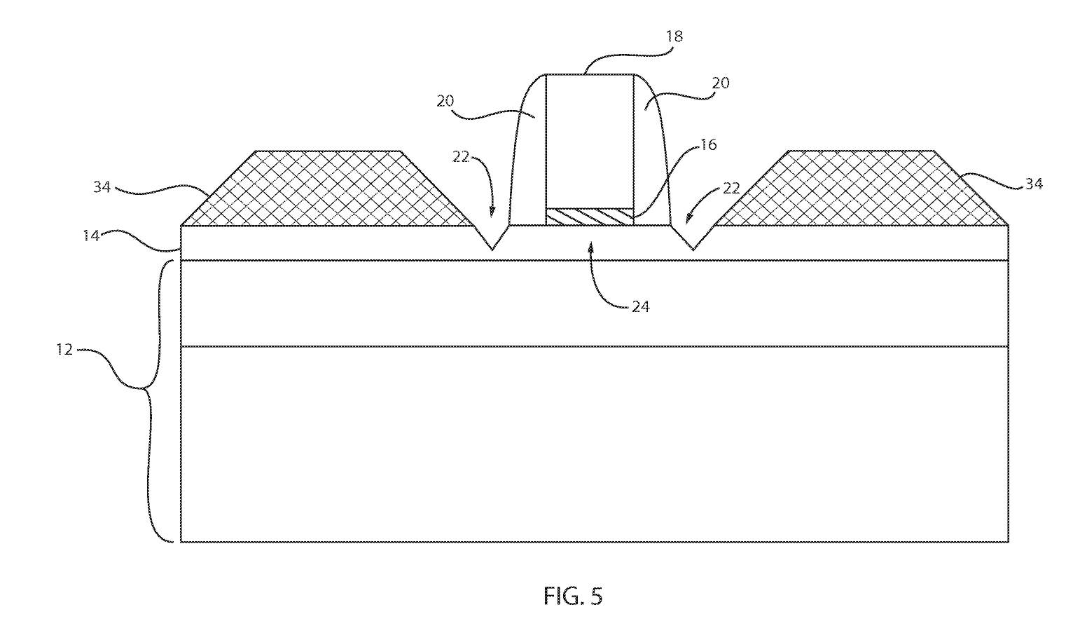

Referring now to FIG. 5, in another embodiment, the semiconductor device of FIG. 1 is processed to grow raised S/D regions 34 above the strained semiconductor layer 14 and at the same time form the self-aligned notches 22. Raised S/D regions 34 may be epitaxially grown with a faceted epitaxy process with higher flow of HCl or other chloride (CO containing gas that otherwise used in a faceted epitaxy process. The growth rate is smaller than the etch rate in the vicinity of the spacer, but the etch is substantially terminated once a (111) surface is reached. As a result, self-aligned notches 22 bound by (111) surfaces are formed.

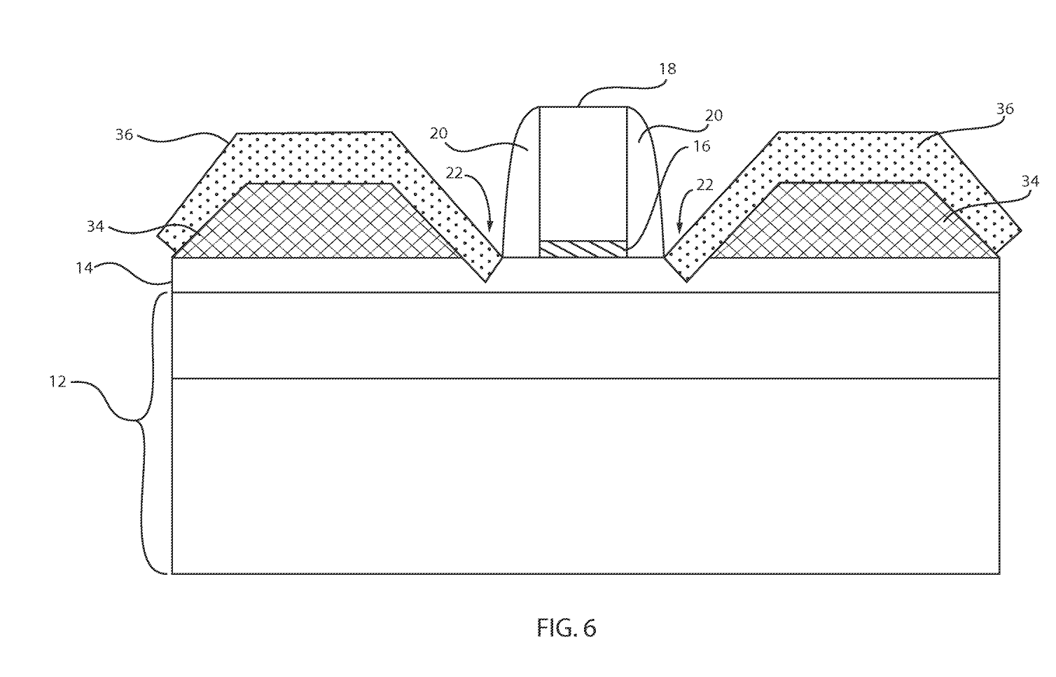

Referring now to FIG. 6, processing of the semiconductor device of FIG. 5 continues to form non-faceted layer 36. A non-faceted epitaxy is employed to epitaxially grow silicon germanium or other semiconductor materials above the raised S/D regions 34 and to fill in the notches 22.

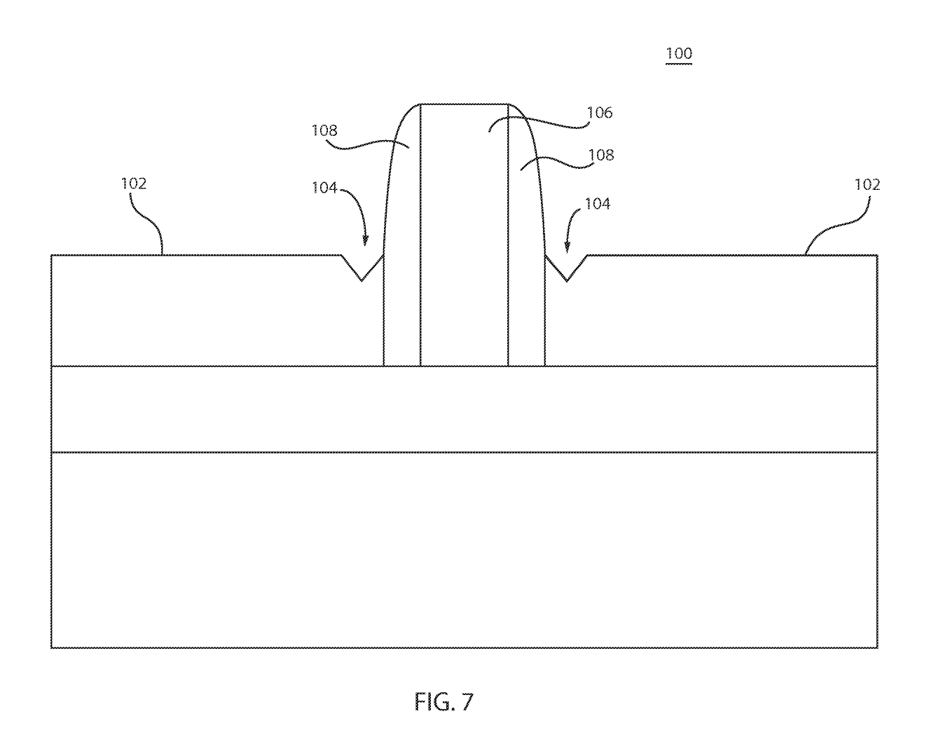

Processing may continue to form a semiconductor device and/or chip. Advantageously, the present embodiments are applicable to other devices or structures as well. For example, the present principles are applicable to finFETs (fin field effect transistors), or other components. Referring now to FIG. 7, a side view of a finFET device 100 is illustratively depicted in accordance with one embodiment of the present principles. Notches 104 are formed in strained fin 102 along an edge of spacers 108 so as to relax the strain. Gate 106 is wrapped around the fin.

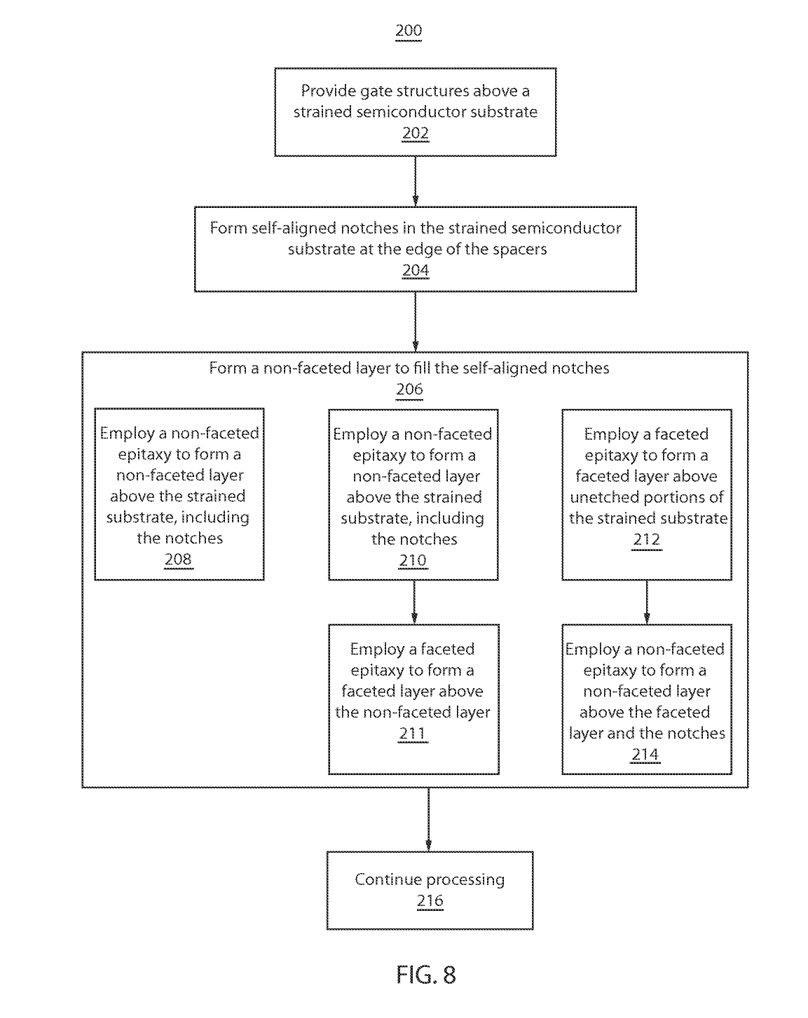

Referring now to FIG. 8, a block/flow diagram showing a method 200 for strain relaxation is illustratively depicted in accordance with one embodiment. In block 202, a semiconductor device includes gate structures formed on a strained semiconductor substrate. The strained semiconductor substrate may include a strained layer formed above a semiconductor substrate, such as, e.g., strained semiconductor directly on insulator. The substrate may include a SOI, bulk substrate, or any other suitable material or combination of materials.

Gate structures are formed in an operative relationship with active areas formed in the strained substrate. The gate structures include a gate electrode isolated from the strained substrate by a gate dielectric. It is noted that the substrate may further include other features or structures formed on or in the substrate in previous processing steps. The gate structures preferably include gate structures for P-type field effect transistors (PFETs) since PFETs see the most improvement from the present example. It should be noted that the present principles may also be applied to N-type field effect transistors (NFETs) as well. Other types of devices are also contemplated. For example, the gate structures may be for fin field effect transistors (finFETs).

In block 204, notches are formed in the strained semiconductor substrate. Preferably, the notches are self-aligned to an edge of the spacers to relax strain in the channel. The self-aligned notches are formed by employing an etching process. In one embodiment, self-aligned notches are formed by flowing an etchant gas (e.g., HCl, etc.) in an epitaxy chamber. In other embodiments, self-aligned spacers may be formed by damaging the strained semiconductor layer during or after spacer formation. Other embodiments are also contemplated.

In block 206, raised S/D regions are formed including a non-faceted layer to fill the self-aligned notches. In one embodiment, in block 208, a non-faceted epitaxial growth process is employed to form the non-faceted layer above the strained substrate, including the notches. The growth rate of non-faceted epitaxial growth is substantially independent of the crystallographic orientation of the semiconductor layer on which the epitaxial layer is grown.

In another embodiment, a two-step epitaxy process is applied. First, in block 210, a non-faceted epitaxial growth process is employed to form the non-faceted layer above the strained substrate, including the notches. In block 211, a faceted epitaxial growth process is employed to form a faceted layer over the non-faceted layer. The growth rate of faceted epitaxial growth is dependent on the crystallographic orientation of the semiconductor layer on which the epitaxial layer is grown. Growth may be non-faceted or faceted by adjusting processing conditions, such as, e.g., temperature, pressure, flow of gases, etc.

In yet another embodiment, in block 212, a faceted epitaxial growth process is employed to form a faceted layer above unetched portions of the strained substrate. In block 214, a non-faceted epitaxial growth process is employed to form a non-faceted layer above the faceted layer and the notches. Advantageously, the parasitic capacitance between a faceted raised S/D structure and the gate is smaller than that of a non-faceted raised S/D structure and the gate.

In block 216, processing continues to form the semiconductor device and/or chip.

Having described preferred embodiments for strain relaxation with self-aligned notch (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

What is claimed is:

1. A semiconductor device, comprising:
a strained semiconductor substrate;
one or more gate structures formed over the strained semiconductor substrate;
one or more spacers formed on the one or more gate structures; and
one or more notches formed in the strained semiconductor substrate, the one or more notches being filled to provide a transistor device having a relaxed channel region.

2. The semiconductor device as recited in claim 1, wherein the one or more notches are self-aligned to an edge of the one or more spacers.

3. The semiconductor device as recited in claim 1, further comprising raised source/drain regions including non-faceted epitaxially grown raised source/drain regions that fill the one or more notches.

4. The semiconductor device as recited in claim 3, wherein the raised source/drain regions further include faceted epitaxially grown source/drain regions formed over the non-faceted epitaxially grown raised source/drain regions.

5. The semiconductor device as recited in claim 1, further comprising:
raised source/drain regions including faceted epitaxially grown raised source/drain regions formed over unetched portions of the strained semiconductor substrate; and
a non-faceted epitaxially grown layer formed over the faceted epitaxially grown raised source/drain regions and the one or more notches.
